(19) United States
(12) Patent Application Publication
(10) Pub. No.: US 2026/0020504 A1
(43) Pub. Date: Jan. 15, 2026

(54) CONDUCTIVE BRIDGING MEMORY DEVICE AND METHOD FOR MANUFACTURING THE SAME

(71) Applicant: National Yang Ming Chiao Tung University, Hsinchu City (TW)

(72) Inventors: Po-Tsun Liu, Hsinchu-City (TW); Kai-Jhih Gan, Kaohsiung City (TW); Yu-Chuan Chiu, Taoyuan City (TW); Chih-Chieh Hsu, Taoyuan City (TW); Shu-Wei Chang, Taipei City (TW); Sheng-Jie Su, Kaohsiung City (TW)

(21) Appl. No.: 18/955,020

(22) Filed: Nov. 21, 2024

(30) Foreign Application Priority Data
Jul. 9, 2024 (TW) 113125679

(51) Int. Cl. H10N 70/00

(52) U.S. Cl. CPC H10N 70/8833; H10N 70/026; H10N 70/841

(57) ABSTRACT

A conductive bridging memory device includes a conductive electrode layer, a resistive switching layer, a blocking layer and a copper electrode layer that are sequentially stacked in such order from bottom to top. The resistive switching layer includes a zinc oxide seed sublayer and a nanopillar sublayer that has a plurality of copper-doped zinc oxide nanopillars extending from the zinc oxide seed sublayer toward the blocking layer. The plurality of copper-doped zinc oxide nanopillars each has a diameter of not greater than 100 nm. The nanopillar sublayer is formed by subjecting a precursor solution containing a reducing agent, zinc acetate and copper acetate to a hydrothermal reaction. The copper acetate is present in an amount ranging from 0.1 wt % to 0.75 wt % based on 100 wt % of the precursor solution. A method for manufacturing a conductive bridging memory device is also provided.

### CROSS-REFERENCE TO RELATED APPLICATION

This application claims priority to Taiwanese Invention patent application No. 113125679, filed on Jul. 9, 2024, the entire disclosure of which is incorporated by reference herein.

### FIELD

The present disclosure relates to a memory device, and more particularly to a conductive bridging memory device. The present disclosure also relates to a method for manufacturing the conductive bridging memory device.

### BACKGROUND

With the development and advancement of science and technology, our daily lives are filled with large numbers of products in the categories of computers, communications and consumer electronics, such as mobile phones and tablet computers. Since such products are required to store massive amount of digital information such as text, music and pictures, the demand of memory devices, such as magnetoresistive memory devices, resistive memory devices, etc., is increasing. Resistive memory device is considered as one of the next generation non-volatile memory devices due to simple structure, fast access speed and power saving characteristics thereof.

Since the resistive memory device is required to carry increased drive current and be operated under quick transition between high-resistance-state (HRS) and low-resistance-state (LRS) (i.e., increased frequency of switching between HRS and LRS), problems of fluctuating resistive switching parameters and unsatisfactory endurance may arise. In addition, for a resistive switching layer made of indium zinc oxide, a number of oxygen vacancies for carrier migration formed on a surface of the resistive switching layer is much greater than that formed within the resistive switching layer, which might lead to current overshoot due to instantaneous current flowing through the surface of the resistive switching layer being too large during voltage application, thereby reducing the service life of the resistive memory device. Therefore, it is important to improve the stability of the resistive memory device in order to prolong the service life thereof.

### SUMMARY

Therefore, an object of the present disclosure is to provide a conductive bridging memory device and a method for manufacturing a conductive bridging memory device that can alleviate at least one of the drawbacks of the prior art.

According to an aspect of the present disclosure, the conductive bridging memory device includes a conductive electrode layer, a resistive switching layer, a blocking layer and a copper electrode layer that are sequentially stacked in such order from bottom to top. The resistive switching layer includes a zinc oxide seed sublayer and a nanopillar sublayer that has a plurality of copper-doped zinc oxide nanopillars extending from the zinc oxide seed sublayer toward the blocking layer. The plurality of copper-doped zinc oxide nanopillars each has a diameter of not greater than 100 nm. The nanopillar sublayer is formed by subjecting a precursor solution containing a reducing agent, zinc acetate and copper acetate to a hydrothermal reaction. The copper acetate is present in an amount ranging from 0.1 wt % to 0.75 wt % based on 100 wt % of the precursor solution.

According to another aspect of the present disclosure, the method for manufacturing the conductive bridging memory device includes the steps of:
immersing a laminate, which includes a carrier plate, a conductive electrode layer and a zinc oxide seed sublayer sequentially stacked in such order from bottom to top, in a precursor solution, followed by conducting a hydrothermal reaction at a temperature ranging from 70° C. to 110° C. for a time period ranging from 30 minutes to 90 minutes, so that a nanopillar sublayer is grown on the zinc oxide seed sublayer opposite to the conductive electrode layer, thereby forming a resistive switching layer including the zinc oxide seed sublayer and the nanopillar sublayer, wherein the nanopillar sublayer has a plurality of copper-doped zinc oxide nanopillars each having a diameter of not greater than 100 nm and extending away from the zinc oxide seed sublayer, and the precursor solution contains a reducing agent, zinc acetate and copper acetate, the copper acetate being present in an amount ranging from 0.1 wt % to 0.75 wt % based on 100 wt % of the precursor solution;
forming a blocking layer on the nanopillar sublayer opposite to the zinc oxide seed sublayer by sputtering technique; and
forming a copper electrode layer on the blocking layer opposite to the nanopillar sublayer by sputtering technique.

### BRIEF DESCRIPTION OF THE DRAWINGS

Other features and advantages of the present disclosure will become apparent in the following detailed description of the embodiment(s) with reference to the accompanying drawings. It is noted that various features may not be drawn to scale.

FIG. 1 is a schematic perspective view illustrating a conductive bridging memory device according to the present disclosure.

FIG. 2 is a photograph of a top view of a resistive switching layer of the conductive bridging memory device, illustrating a plurality of copper-doped zinc oxide nanopillars of a nanopillar sublayer according to the present disclosure.

FIG. 3 is a photograph of a side view of the resistive switching layer of the conductive bridging memory device, illustrating the copper-doped zinc oxide nanopillars of the nanopillar sublayer according to the present disclosure.

FIG. 4 is a current-voltage curve of a memory device of Comparative Example 1 (CE1) that is subjected to transition between high-resistance-state (HRS) and low-resistance-state (LRS) for 1 time, 50 times and 100 times.

FIG. 5 is a current-voltage curve of a memory device of Comparative Example 2 (CE2) that is subjected to transition between HRS and LRS for 1 time, 30 times and 60 times.

FIG. 6 is a current-voltage curve of a conductive bridging memory device of Example 1 (E1) that is subjected to transition between HRS and LRS for 1 time, 50 times and 100 times.

FIG. 7 is a current-voltage curve of a conductive bridging memory device of Example 2 (E2) that is subjected to transition between HRS and LRS for 1 time, 50 times and 100 times.

FIG. 8 is a current-voltage curve of a conductive bridging memory device of Example 3 (E3) that is subjected to transition between HRS and LRS for 1 time, 50 times and 100 times.

FIG. 9 is a box-and-whisker diagram showing set voltage of the memory device of CE1 and the conductive bridging memory devices of E1 to E3.

FIG. 10 is a box-and-whisker diagram showing reset voltage of the memory device of CE1 and the conductive bridging memory devices of E1 to E3.

FIG. 11 is a plot showing current distribution in HRS and LRS of the memory device of CE1 under different times of transition between the HRS and the LRS.

FIG. 12 is a plot showing current distribution in HRS and LRS of the conductive bridging memory device of E3 under different times of transition between the HRS and the LRS.

### DETAILED DESCRIPTION

Before the present disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

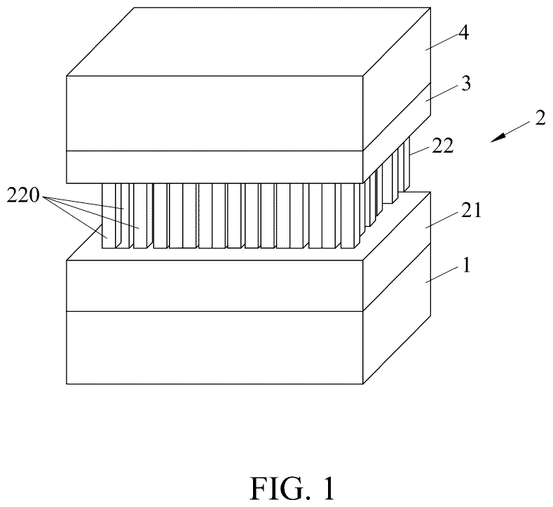

Referring to FIGS. 1 to 3, a conductive bridging memory device according to the present disclosure includes a conductive electrode layer 1, a resistive switching layer 2, a blocking layer 3 and a copper electrode layer 4 that are sequentially stacked in such order from bottom to top.

The conductive electrode layer 1 includes a first conductive material, which may be a relatively inert conductive material. Examples of the first conductive material may include, but are not limited to, platinum, palladium, and tungsten. In certain embodiments, the conductive electrode layer 1 may be a platinum electrode layer, a palladium electrode layer or a tungsten electrode layer. In certain embodiments, the conductive electrode layer 1 has a thickness of 100 nm.

The resistive switching layer 2 includes a zinc oxide seed sublayer 21 and a nanopillar sublayer 22. The zinc oxide seed sublayer 21 is disposed on the conductive electrode layer 1, and is used as a growth layer to assist in promoting the formation of the nanopillar sublayer 22 of the resistive switching layer 2. In certain embodiments, the zinc oxide seed sublayer 21 has a thickness of 25 nm.

The nanopillar sublayer 22 is disposed on the zinc oxide seed sublayer 21 opposite to the conductive electrode layer 1, and has a plurality of copper-doped zinc oxide nanopillars 220 extending from the zinc oxide seed sublayer toward the blocking layer 3. The nanopillar sublayer 22 is formed by subjecting a precursor solution containing a reducing agent, zinc acetate and copper acetate to a hydrothermal reaction. The copper acetate is present in an amount ranging from 0.1 wt % to 0.75 wt % based on 100 wt % of the precursor solution. In certain embodiments, the nanopillar sublayer 22 has a thickness ranging from 90 nm to 500 nm. In certain embodiments, the copper-doped zinc oxide nanopillars 220 each has a diameter ranging from 40 nm to 100 nm.

The blocking layer 3 is disposed on the nanopillar sublayer 22 of the resistive switching layer 2 opposite to the zinc oxide seed sublayer 21, and serves as a buffer to prevent a large amount of copper ions of the copper electrode layer 4 from entering the resistive switching layer 2 during operation of the conductive bridging memory device. The blocking layer 3 includes a second conductive material. Examples of the second conductive material may include, but are not limited to, titanium tungsten, titanium and titanium nitride. In certain embodiments, the blocking layer 3 may be a titanium tungsten layer, a titanium layer or a titanium nitride layer. In certain embodiments, the blocking layer 3 has a thickness of 1.5 nm.

The copper electrode layer 4 is disposed on the blocking layer 3 opposite to the nanopillar sublayer 22. In certain embodiments, the copper electrode layer 4 has a thickness of 100 nm.

When the conductive bridging memory device is in use, during the SET process, a positive bias voltage applied to the copper electrode layer 4 will cause the same to undergo oxidation so as to release copper ions that drift towards the conductive electrode layer 1 due to the presence of electric field and that reach the blocking layer 3. The blocking layer 3 serves as a buffer region to prevent a large amount of copper ions from entering the resistive switching layer 2 within a short time period, so as to avoid damage to the conductive bridging memory device due to large difference in voltage drop between the copper electrode layer 4 and the resistive switching layer 2. Then, the copper ions reaching the resistive switching layer 2 migrate to the conductive electrode layer 1 along the conductive pathways formed by the oxygen vacancies of the resistive switching layer 2 to gradually accumulating upwardly from the conductive electrode layer 1, and then are reduced to copper metal deposited at the conductive electrode layer 1 and along the conductive pathways, so as to form conductive filaments (Cu filaments) between the copper electrode layer 4 and the conductive electrode layer 1. As a result, the conductive bridging memory device is at low-resistance-state (LRS). In contrast, during the RESET process, when a negative bias voltage is applied to the copper electrode layer 4, a Joule heating effect is induced and the conductive bridging memory device generates energy to rupture the conductive filaments, resulting in the conductive bridging memory device being switched back to high-resistance-state (HRS). By adjusting the applied voltage, transition of the conductive bridging memory device between the LRS and the HRS can be controlled.

A method for manufacturing the conductive bridging memory device of the present disclosure includes the following steps (A) to (C).

In step (A), a laminate, which includes the zinc oxide seed sublayer 21, the conductive electrode layer 1, an adhesive layer (not shown in the figures), and a carrier plate (not shown in the figures) sequentially stacked in such order from top to bottom, is immersed in the precursor solution, followed by conducting the hydrothermal reaction at a temperature ranging from 70° C. to 110° C. for a time period ranging from 30 minutes to 90 minutes, so that the nanopillar sublayer 22 is grown on the zinc oxide seed sublayer 21 opposite to the conductive electrode layer 1, thereby forming the resistive switching layer 2 including the nanopillar sublayer 22 and the zinc oxide seed sublayer 21. The nanopillar sublayer 22 has a plurality of the copper-doped zinc oxide nanopillars 220 each having a diameter of not greater than 100 nm and extending away from the zinc oxide seed sublayer 21. The precursor solution contains the reducing agent, zinc acetate and copper acetate. The copper acetate is present in an amount ranging from 0.1 wt % to 0.75 wt % based on 100 wt % of the precursor solution. In certain embodiments, the nanopillar sublayer 22 has a thickness ranging from 90 nm to 500 nm.

In step (B), the blocking layer 3 is formed on the nanopillar sublayer 22 of the resistive switching layer 2 opposite to the zinc oxide seed sublayer 21 by sputtering technique.

In step (C), the copper electrode layer 4 is formed on the blocking layer 3 opposite to the nanopillar sublayer 22 by sputtering technique.

Examples of the carrier plate include, but are not limited to, a quartz carrier plate, a sapphire carrier plate, a glass substrate, and a polymer substrate. Examples of the polymer substrate include, but are not limited to, a soft polymer substrate and a hard polymer substrate. Examples of the soft polymer substrate include, but are not limited to, a polyethylene terephthalate (PET) substrate, a polyethylene naphthalate (PEN) substrate, and a polycarbonate substrate. An example of the adhesive layer includes a titanium layer. The adhesive layer is used to increase adhesion between the conductive electrode layer 1 and the carrier plate, and is formed by plating titanium metal on the carrier plate using sputtering technique. In certain embodiments, the adhesion layer has a thickness of 5 nm. The conductive electrode layer 1 of the laminate is formed by plating the first conductive material on the adhesion layer using sputtering technique. The zinc oxide seed sublayer 21 of the laminate is formed by plating zinc oxide on the conductive electrode layer 1 using sputtering technique.

An example of the reducing agent includes hexamethylenetetramine. An example of the zinc acetate includes zinc acetate dihydrate [Zn(CH₃COO)₂·2H₂O]. An example of the copper acetate includes copper(II) acetate monohydrate. In certain embodiments, the zinc acetate in the precursor solution has a concentration ranging from 0.02 M to 0.05 M.

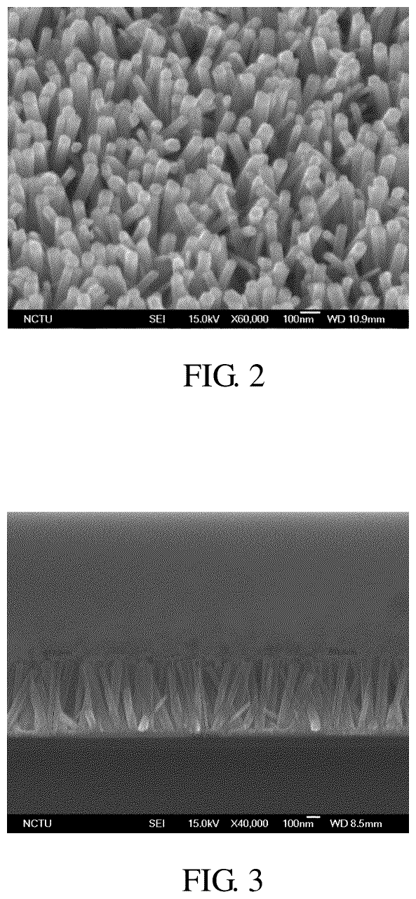

As shown in FIGS. 2 and 3, by conducting the hydrothermal reaction, the method for manufacturing the conductive bridging memory device of the present disclosure is capable of precisely controlling the growth of the copper-doped zinc oxide nanopillars 220, so that the copper-doped zinc oxide nanopillars 220 exhibit consistent growth and high degree of growth in a vertical direction (i.e., extending from the zinc oxide seed sublayer 21 toward the blocking layer 3). As shown in FIGS. 2 and 3, the copper-doped zinc oxide nanopillars 220 each is observed to have a diameter of approximately 40 nm.

The blocking layer 3 is formed by plating the second conductive material on the nanopillar layer 22 of the resistive switching layer 2 opposite to the conductive electrode layer 1 using sputtering technique. Examples of the second conductive material include, but are not limited to, titanium tungsten, titanium and titanium nitride. The blocking layer 3 serves as a buffer layer to prevent a large amount of copper ions from entering the resistive switching layer 2 within a short time period, so as to avoid the problem of a large difference in voltage drop between the copper electrode layer 4 and the resistive switching layer 2.

The copper electrode layer 4 is formed by plating copper on the blocking layer 3 opposite to the nanopillar sublayer 22 using sputtering technique.

It should be noted that, since a process temperature of a sputtering process can be controlled to range from room temperature to 120° C., selection of material for making the carrier plate is flexible, and the sputtering process has advantages of large film formation area and accurate control of film thickness.

The present disclosure will be described by way of the following examples. However, it should be understood that the following examples are intended solely for the purpose of illustration and should not be construed as limiting the present disclosure in practice.

### Example 1 (E1)

The procedures for manufacturing a conductive bridging memory device of E1 includes the following steps (a) to (f).

In step (a), a titanium layer (serving as an adhesive layer) having a thickness of 5 nm was formed by plating titanium on a glass substrate using direct current sputtering technique conducted under argon atmosphere at ambient pressure of 3×10⁻³ Torr, thereby obtaining a first laminate.

In step (b), a platinum layer (serving as a conductive electrode layer) having a thickness of 100 nm was formed by plating platinum on the titanium layer opposite to the glass substrate using direct current sputtering technique conducted under argon atmosphere at ambient pressure of 3×10⁻³ Torr, thereby obtaining a second laminate.

In step (c), a zinc oxide seed layer having a thickness of 25 nm was formed by plating zinc oxide on the platinum layer opposite to the adhesive layer using radio frequency magnetron sputtering technique conducted under argon and oxygen atmosphere [a gas flow rate (sccm) ratio of argon to oxygen was 20:5] at ambient pressure of 3 mTorr and radio frequency power of 50 watt, thereby obtaining a third laminate.

In step (d), the third laminate was immersed in a beaker containing a precursor solution, followed by sealing the beaker and conducting a hydrothermal reaction at 90° C. for 30 minutes, so that a nanopillar layer including a plurality of copper-doped zinc oxide nanopillars each having a length of 460 nm and a diameter of 40 nm was grown on the zinc oxide seed sublayer, thereby obtaining a fourth laminate including a resistive switching layer which included the zinc oxide seed sublayer and the nanopillar layer, which was formed opposite to the adhesive layer, and which had a thickness of 485 nm. In this step, the third laminate was obliquely immersed in the beaker, where the third laminate slants relative to a bottom surface of the beaker by 70°. The precursor solution contained zinc acetate dihydrate (purity: 99.9%), hexamethylenetetramine (purity: 99.9%), copper(II) acetate monohydrate, and deionized water. In the precursor solution, the zinc acetate dehydrate had a concentration of 0.02 M, the copper(II) acetate monohydrate was present in an amount of 0.25 wt % based on 100 wt % of the precursor solution, and a molar ratio of zinc ions of the zinc acetate dehydrate to the hydroxide ions (OH⁻) of the hexamethylenetetramine was 1:1.

In step (e), a titanium tungsten layer (serving as a blocking layer) having a thickness of 1.5 nm was formed by plating titanium tungsten on the nanopillar sublayer of the resistive switching layer opposite to the zinc oxide seed sublayer using direct current sputtering technique conducted under argon atmosphere at ambient pressure of 3×10⁻³ Torr, thereby obtaining a fifth laminate. In step (f), a copper electrode layer having a thickness of 100 nm was formed by utilizing photomasks and plating copper on the titanium tungsten layer opposite to the nanopillar sublayer using direct current sputtering technique conducted under argon atmosphere at ambient pressure of 3×10⁻³ Torr, thereby obtaining the conductive bridging memory device of E1. The copper electrode layer includes a plurality of copper cylinders spaced apart from each other and each having a diameter of 100 μm.

### Examples 2 and 3 (E2 and E3)

The procedures for manufacturing the conductive bridging memory devices of E2 and E3 were substantially similar to those of E1, except for the following differences: (i) in step (d), based on 100 wt % of the precursor solution, the contents of copper(II) acetate monohydrate in the precursor solutions of E2 and E3 were 0.5 wt % and 0.75 wt %, respectively; (ii) in E2, the thickness of the resistive switching layer was 445 nm, and the length and the diameter of each of the copper-doped zinc oxide nanopillars were approximately 420 nm and 50 nm, respectively; and (iii) in E3, the thickness of the resistive switching layer was 525 nm, and the length and the diameter of each of the copper-doped zinc oxide nanopillars were approximately 500 nm and 60 nm, respectively.

### Comparative Example 1 (CE1)

The procedures for manufacturing the memory device of CE1 were substantially similar to those of E1, except for the following differences: (i) in step (d), the precursor solution was free of copper(II) acetate monohydrate; and (ii) in CE1, the thickness of the resistive switching layer was 475 nm, and the length and the diameter of each of the copper-doped zinc oxide nanopillars were approximately 450 nm and 40 nm, respectively.

### Comparative Example 2 (CE2)

The procedures for manufacturing the memory device of CE2 were substantially similar to those of E1, except for the following differences: (i) in step (d), based on 100 wt % of the precursor solution, the content of copper(II) acetate monohydrate in the precursor solution of CE2 was 1 wt %; and (ii) in CE2, the thickness of the resistive switching layer was 265 nm, and the length and the diameter of each of the copper-doped zinc oxide nanopillars were approximately 240 nm and 70 nm, respectively.

### Property Evaluation

### 1. Measurement of Current-Voltage

A respective one of the conductive bridging memory devices of E1 to E3 and the memory device of CE1 was subjected to transition between high-resistance-state (HRS) and low-resistance-state (LRS) for 1 time, 50 times and 100 times while the memory device of CE2 was subjected to the HRS and the LRS for 1 time, 30 times and 60 times, and measurement of current-voltage was conducted using a Parameter Analyzer (Manufacturer: Keithley Instruments; Model no.: 4200-SCS). During measurement, in a respective one of the conductive bridging memory devices of E1 to E3 and the memory devices of CE1 and CE2, the conductive electrode layer was grounded and the copper electrode layer was connected to the voltage source of the Parameter Analyzer, while a voltage loop of 0 volt→+4 volt→0 volt→−2 volt→0 volt and a quiescent supply current (I_{cc}) of 10 mA were applied.

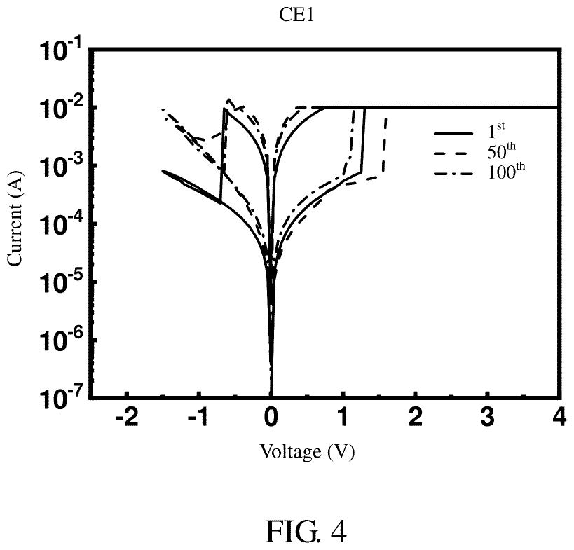

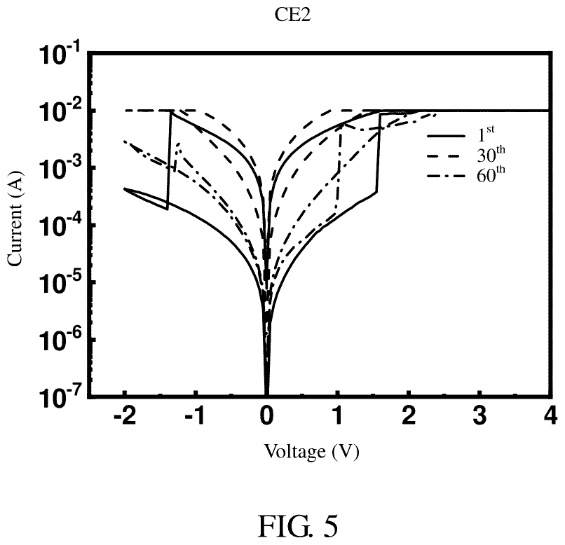

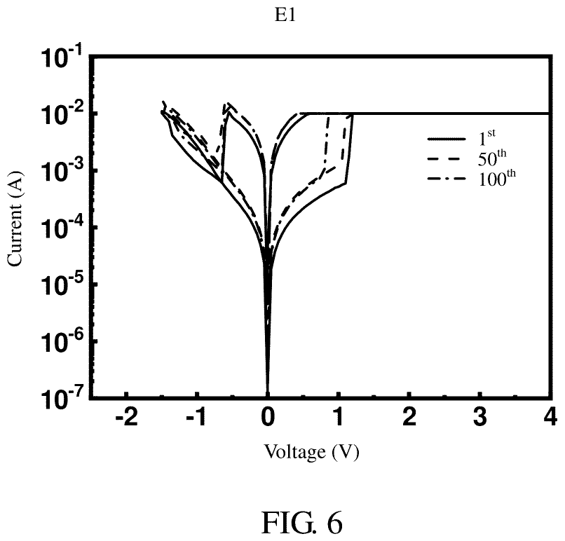

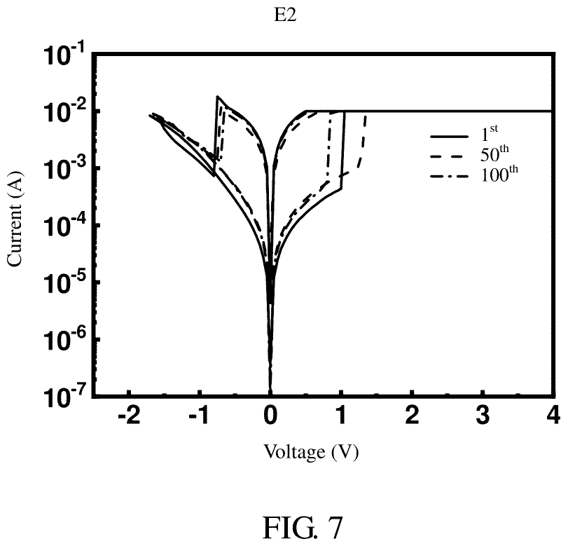

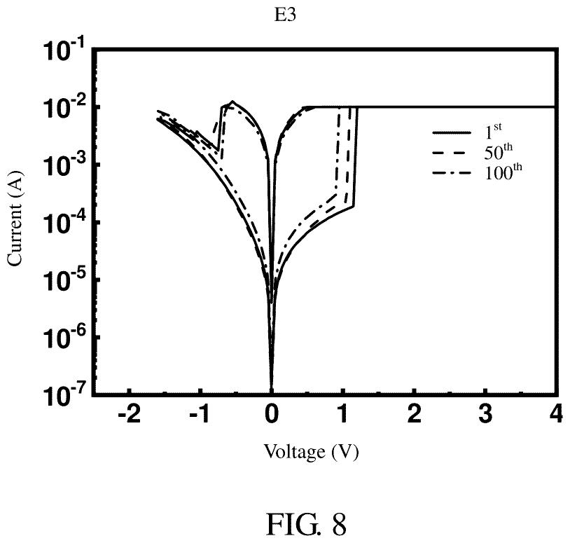

The results are shown in FIGS. 4 to 8.

### 2. Measurement of Set Voltage and Reset Voltage

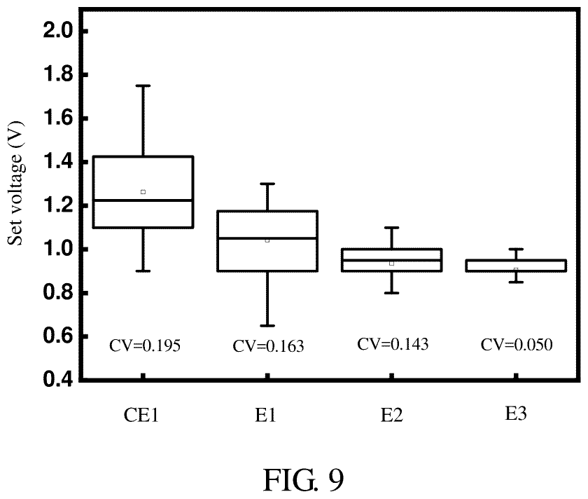

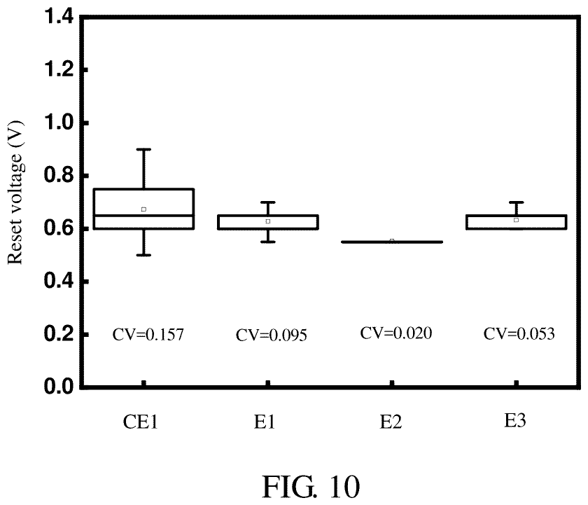

A respective one of the conductive bridging memory devices of E1 to E3 and the memory devices of CE1 and CE2 was subjected to transition between HRS and LRS for 100 times, and measurements of set voltage and reset voltage were conducted using the Parameter Analyzer (Manufacturer: Keithley Instruments; Model no.: 4200-SCS). Thereafter, average value and standard deviation of the set voltage and those of the reset voltage were determined, followed by determining the coefficients of variations (abbreviated as “CV”) of the set voltage and the reset voltage. The results are shown in FIGS. 9 and 10.

### 3. Determination of Device Endurance (Durability)

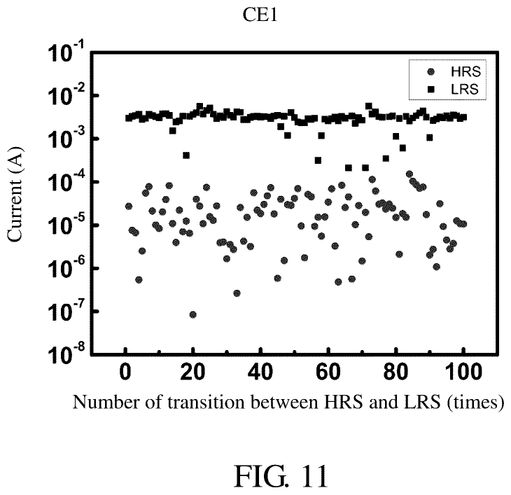

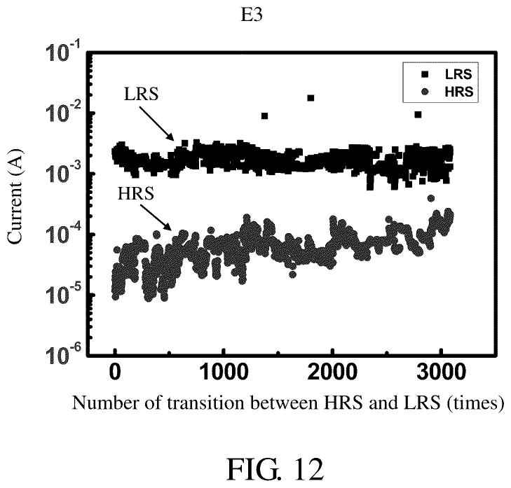

A respective one of the conductive bridging memory device of E3 and the memory device of CE1 was repeatedly subjected to transition between HRS and LRS, and currents in the HRS and the LRS were measured using the Parameter Analyzer (Manufacturer: Keithley Instruments; Model no.: 4200-SCS). During measurement, a read voltage of −0.1 volt was applied, and the currents in the HRS and the LRS were measured during each transition until device failure (breakdown) occurred. The device endurance was determined by the cumulative number of times the transition between the HRS and the LRS at the point of device failure. The results are shown in FIGS. 11 and 12.

Referring to FIGS. 4 to 8, after multiples times of transition between the HRS and the LRS, the current-voltage curves of the conductive bridging memory devices of E1 to E3 were substantially similar in terms of reproducibility and uniformity, whereas with increased times of transition between the HRS and the LRS, the current-voltage curves of the memory devices of CE1 and CE2 showed poor reproducibility and poor uniformity, i.e., the current-voltage curves of the conductive bridging memory devices of E1 to E3 exhibited less fluctuations. These results indicate that, by virtue of inclusion of the copper-doped zinc oxide nanopillars 220 of the nanopillar sublayer 22 in the resistive switching layer 2, the conductive bridging memory device of the present disclosure has improved stability. In addition, since the conductive bridging memory device of the present disclosure can be operated at low voltage, such conductive bridging memory device has reduced operating power consumption.

Referring to FIGS. 9 and 10, in comparison with the memory device of CE1, the set voltage and the reset voltage of each of the conductive bridging memory devices of E1 to E3 were relatively smaller with less deviation, i.e., more uniformity with lower overall voltage. As shown in FIGS. 9 and 10, the coefficient of variation of the set voltage and the coefficient of variation of the reset voltage of the memory device of CE1 were 0.195 and 0.157, respectively, the coefficients of variations of the set voltages of the conductive bridging memory devices of E1 to E3 were 0.163, 0.143 and 0.050, respectively, and the coefficients of variations of the reset voltages of the conductive bridging memory devices of E1 to E3 were 0.095, 0.020 and 0.053, respectively. These results indicate that, by virtue of inclusion of the copper-doped zinc oxide nanopillars 220 of the nanopillar sublayer 22 in the resistive switching layer 2, the coefficients of variations of set voltage and reset voltage of the conductive bridging memory device of the present disclosure is relatively small, suggesting that the conductive bridging memory device has improved stability, which is conducive for the operation of writing/erasing information under a low voltage.

Referring to FIGS. 11 and 12, in comparison with the memory device of CE1, in which the cumulative number of times the transition between the HRS and the LRS when breakdown thereof occurred was approximately 100 times, the cumulative number of times the transition between the HRS and the LRS when breakdown of the conductive bridging memory device of E3 occurred was much higher, which was approximately 3000 times (i.e., 30 times improvement). These result indicate that, by virtue of inclusion of the copper-doped zinc oxide nanopillars 220 of the nanopillar sublayer 22 in the resistive switching layer 2, the conductive bridging memory device of the present disclosure has a high stability during the operation of repeatedly writing/erasing information, and improved durability.

In summary, by virtue of inclusion of the copper-doped zinc oxide nanopillars 220 of the nanopillar sublayer 22 in the resistive switching layer 2, the conductive bridging memory device of the present disclosure, during the operation of repeatedly writing/erasing information, has advantage of exhibiting relatively small variations in the set voltage and the reset voltage, and thus, has reduced operating power consumption and improved stability. In addition, by virtue of conducting the hydrothermal reaction to form the nanopillar sublayer 22, the method for manufacturing the conductive bridging memory device of the present disclosure, in comparison with a conventional manufacturing method, has advantages of low energy consumption and low manufacturing cost, and at the same time, allows the growth of the copper-doped zinc oxide nanopillars 220 to be precisely controlled, such that the copper-doped zinc oxide nanopillars 220 have consistent growth and high degree of growth in a vertical direction (i.e., extending from the zinc oxide seed sublayer 21 toward the blocking layer 3). Therefore, the purpose of the present disclosure can indeed be achieved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A conductive bridging memory device, comprising:
a conductive electrode layer, a resistive switching layer, a blocking layer and a copper electrode layer that are sequentially stacked in such order from bottom to top, the resistive switching layer including a zinc oxide seed sublayer and a nanopillar sublayer that has a plurality of copper-doped zinc oxide nanopillars extending from the zinc oxide seed sublayer toward the blocking layer, the plurality of copper-doped zinc oxide nanopillars each having a diameter of not greater than 100 nm,
wherein the nanopillar sublayer is formed by subjecting a precursor solution containing a reducing agent, zinc acetate and copper acetate to a hydrothermal reaction, the copper acetate being present in an amount ranging from 0.1 wt % to 0.75 wt % based on 100 wt % of the precursor solution.

2. The conductive bridging memory device as claimed in claim 1, wherein the plurality of copper-doped zinc oxide nanopillars each has a diameter ranging from 40 nm to 100 nm.

3. The conductive bridging memory device as claimed in claim 1, wherein the conductive electrode layer is selected from the group consisting of a platinum electrode layer, a palladium electrode layer, and a tungsten electrode layer.

4. The conductive bridging memory device as claimed in claim 3, wherein the conductive electrode layer is the platinum electrode layer.

5. The conductive bridging memory device as claimed in claim 1, wherein the blocking layer is selected from the group consisting of a titanium tungsten layer, a titanium layer, and a titanium nitride layer.

6. The conductive bridging memory device as claimed in claim 5, wherein the blocking layer is the titanium tungsten layer.

7. The conductive bridging memory device as claimed in claim 1, wherein the nanopillar sublayer has a thickness ranging from 90 nm to 500 nm.

8. A method for manufacturing a conductive bridging memory device, comprising the steps of:
immersing a laminate, which includes a carrier plate, a conductive electrode layer and a zinc oxide seed sublayer sequentially stacked in such order from bottom to top, in a precursor solution, followed by conducting a hydrothermal reaction at a temperature ranging from 70° C. to 110° C. for a time period ranging from 30 minutes to 90 minutes, so that a nanopillar sublayer is grown on the zinc oxide seed sublayer opposite to the conductive electrode layer, thereby forming a resistive switching layer including the zinc oxide seed sublayer and the nanopillar sublayer, wherein the nanopillar sublayer has a plurality of copper-doped zinc oxide nanopillars each having a diameter of not greater than 100 nm and extending away from the zinc oxide seed sublayer, and the precursor solution contains a reducing agent, zinc acetate and copper acetate, the copper acetate being present in an amount ranging from 0.1 wt % to 0.75 wt % based on 100 wt % of the precursor solution;
forming a blocking layer on the nanopillar sublayer opposite to the zinc oxide seed sublayer by sputtering technique; and
forming a copper electrode layer on the blocking layer opposite to the nanopillar sublayer by sputtering technique.

9. The method as claimed in claim 8, wherein the reducing agent is hexamethylenetetramine.

10. The method as claimed in claim 8, wherein the conductive electrode layer is selected from the group consisting of a platinum electrode layer, a palladium electrode layer, and a tungsten electrode layer.

11. The method as claimed in claim 10, wherein the conductive electrode layer is the platinum electrode layer.

12. The method as claimed in claim 8, wherein blocking layer is selected from the group consisting of a titanium tungsten layer, a titanium layer, and a titanium nitride layer.

13. The method as claimed in claim 12, wherein the blocking layer is the titanium tungsten layer.

14. The method as claimed in claim 8, wherein the nanopillar sublayer has a thickness ranging from 90 nm to 500 nm.
